(19) United States
(12) Patent Application Publication
(10) Pub. No.: US 2007/0072358 A1
(43) Pub. Date: Mar. 29, 2007

(54) Method of manufacturing metal-oxide-semiconductor transistor devices

(76) Inventors: Chih-Ning Wu, Hsin-Chu City (TW); Chung - Ju Lee, Hsin-Chu Hsien (TW); Wei-Tsun Shiau, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/162,954

(22) Filed: Sep. 29, 2005

(51) Int. Cl. H01L 21/8238; H01L 21/44

(52) U.S. Cl. 438/233; 438/656; 257/E21.409; 257/E29.156

(57) ABSTRACT

A method of manufacturing a metal-oxide-semiconductor transistor device is disclosed. In the method, a silicon nitride spacer is formed and will be removed after an ion implantation process to form a source/drain region and a salicide process to form a metal silicide layer on the surface of the source/drain region and the gate electrode. The metal silicide layer is formed to comprise silicon (Si), nickel (Ni) and at least one metal selected from a group consisting of iridium (Ir), iron (Fe), cobalt (Co), platinum (Pt), palladium (Pd), molybdenum (Mo), and tantalum (Ta); therefore, when the silicon nitride spacer is removed by etching, the metal silicide layer is not damaged.

### BACKGROUND OF THE INVENTION

1. Field of the Invention

The present invention relates to a semiconductor transistor device, and more particularly to a method of manufacturing a silicon nitride spacer-less semiconductor transistor device, having an improvement for preventing a metal silicide layer from being damaged while a spacer is removed.

2. Description of the Prior Art

High-speed metal-oxide-semiconductor (MOS) transistor devices have been proposed in which a strained silicon (Si) layer, such as an epitaxially grown silicon germanium (SiGe) layer on a Si wafer, is used for the channel area. In this type of strained Si-FET, a biaxial tensile strain occurs in the silicon layer due to the SiGe which has a larger lattice constant than Si, and as a result, the Si band structure alters, and the carrier mobility increases. Consequently, using this strained Si layer for a channel area typically enables a 1.5 to 8-fold speed increase.

FIGS. 1-3 are schematic cross-sectional diagrams illustrating a prior art method of fabricating a semiconductor NMOS transistor device 10. As shown in FIG. 1, the conventional NMOS transistor device 10 generally includes a semiconductor substrate generally comprising a silicon layer 16 having a source 18 and a drain 20 separated by a channel region 22. The silicon layer 16 is typically a strained silicon layer formed by epitaxially growing a silicon layer on a SiGe layer (not shown). Ordinarily, the source 18 and drain 20 further border a shallow-junction source extension 17 and a shallow-junction drain extension 19, respectively. A thin oxide layer 14 separates a gate 12, generally comprising polysilicon, from the channel region 22.

In the device 10 illustrated in FIG. 1, the source 18 and drain 20 are N+ regions having been doped by arsenic, antimony or phosphorous. The channel region 22 is generally boron doped. A silicon nitride spacer 32 is formed on sidewalls of the gate 12. A liner 30, generally comprising silicon dioxide, is interposed between the gate 12 and the silicon nitride spacer 32. A salicide layer 42 is selectively formed on the exposed silicon surface of the device 10. The process known as self-aligned silicide (salicide) process has been widely utilized to fabricate silicide materials, in which a source/drain region is first formed, a metal layer comprised of cobalt, titanium, or nickel is disposed on the source/drain region and the gate structure, and a rapid thermal process (RTP) is performed to react the metal layer with the silicon contained within the gate structure and the source/drain region to form a metal silicide for reducing the sheet resistance of the source/drain region.

Referring to FIG. 2, after forming the NMOS transistor device 10, a silicon nitride cap layer 46 is typically deposited thereon. As shown in FIG. 2, the silicon nitride cap layer 46 covers the salicide layer 42 and the silicon nitride spacer 32. The thickness of the silicon nitride cap layer 46 is typically in the range of between 200 angstroms and 400 angstroms for subsequent etching stop purposes. A dielectric layer 48 such as silicon oxide or the like is deposited over the silicon nitride cap layer 46. The dielectric layer 48 is typically much thicker than the silicon nitride cap layer 46.

Referring to FIG. 3, subsequently, conventional lithographic and etching processes are carried out to form a contact hole 52 in the dielectric layer 48 and in the silicon nitride cap layer 46. As aforementioned, the silicon nitride cap layer 46 acts as an etching stop layer during the dry etching process to alleviate source/drain damage caused by the etchant substances.

However, the silicon nitride spacer 32 is left in-situ, resulting a reduced saturation current (Idsat), in addition to a consumption of a certain device volume.

Thus, a need exists in this industry to provide an inexpensive method for making a MOS transistor device having improved functionality and performance.

### SUMMARY OF THE INVENTION

It is an object of the present invention to provide a method of manufacturing a silicon nitride spacer-less semiconductor MOS transistor devices having improved performance, in which the spacer can be removed without damaging the salicide layer.

According to the present invention, the method of manufacturing a MOS transistor device comprises steps as follows. A semiconductor substrate having a main surface is prepared. A gate dielectric layer is formed on the main surface. A gate electrode is patterned on the gate dielectric layer. The gate electrode has sidewalls and a top surface. A liner is formed on the sidewalls of the gate electrode. A silicon nitride spacer is formed on the liner. The main surface is then ion implanted using the gate electrode and the silicon nitride spacer as an implantation mask, thereby forming a source/drain region of the MOS transistor device in the main surface. A salicide layer is formed on the surface of the source/drain region and the gate electrode. The salicide layer comprises silicon (Si), nickel (Ni) and at least one metal selected from a group consisting of iridium (Ir), iron (Fe), cobalt (Co), platinum (Pt), palladium (Pd), molybdenum (Mo), and tantalum (Ta). The silicon nitride spacer is removed.

From another aspect of the present invention, a method of avoiding NiSi layer damage during SiN spacer removal in a semiconductor process is also provided. The method comprises steps as follows. A semiconductor substrate having a gate electrode having sidewalls and a top surface, a liner on the sidewalls of the gate electrode, a silicon nitride spacer on the liner, a source region and a drain region separated by a channel region under the gate electrode, and a NiSi layer on the source region, the drain region, and the gate electrode is prepared. A layer of at least one metal selected from a group consisting of iridium (Ir), iron (Fe), cobalt (Co), platinum (Pt), palladium (Pd), molybdenum (Mo), and tantalum (Ta) is formed on the NiSi layer. Then, an annealing process is performed; thereby the layer of at least one metal reacts with the NiSi layer to form a metal silicide layer. Therefore, when the silicon nitride spacer is removed by a wet etching process with an etchant containing phosphoric acid, the metal silicide layer is not damaged.

From still another aspect of the present invention, a MOS transistor device is also provided. The MOS transistor device comprises a semiconductor substrate having a main surface; a gate dielectric layer on the main surface; a gate electrode on the gate dielectric layer, wherein the gate electrode has sidewalls and a top surface; a liner on the sidewalls of the gate electrode; a source region in the main surface; a drain region separated from the source region by a channel region under the gate electrode; and a salicide layer on the source region and the drain region. The salicide layer comprises silicon (Si), nickel (Ni) and at least one metal selected from a group consisting of iridium (Ir), iron (Fe), cobalt (Co), platinum (Pt), palladium (Pd), molybdenum (Mo), and tantalum (Ta). There is no spacer left on the sidewalls of the gate electrode.

In the present invention method, the SiN spacer can be removed without damaging the metal silicide layer, thus the MOS transistor may have a smaller volume, be allowed to retain good qualities, and further advantage a novel MOS design. For example, when the MOS transistor having the spacer removed is further capped with a stressed silicon nitride cap layer, the cap layer is therefore disposed closer to the channel of the device, resulting in improved performance in terms of increased saturation current.

These and other objectives of the present invention will no doubt become obvious to those of ordinary skill in the art after reading the following detailed description of the preferred embodiment that is illustrated in the various figures and drawings.

### DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-3 are schematic cross-sectional diagrams illustrating a conventional method of fabricating a semiconductor NMOS transistor device; and

FIGS. 4-8 are schematic cross-sectional diagrams illustrating a method of fabricating semiconductor MOS transistor devices in accordance with one preferred embodiment of the present invention.

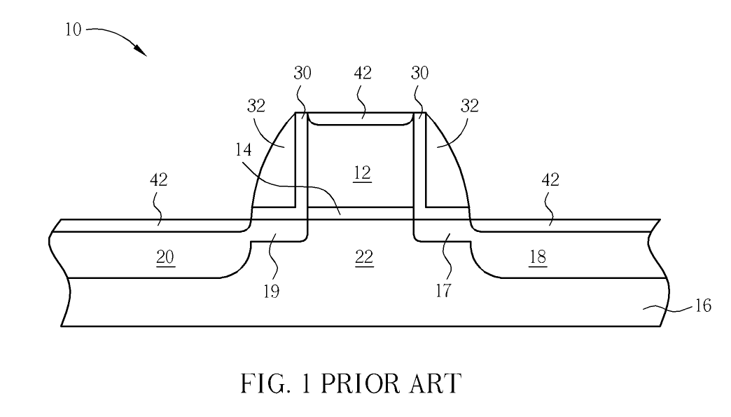

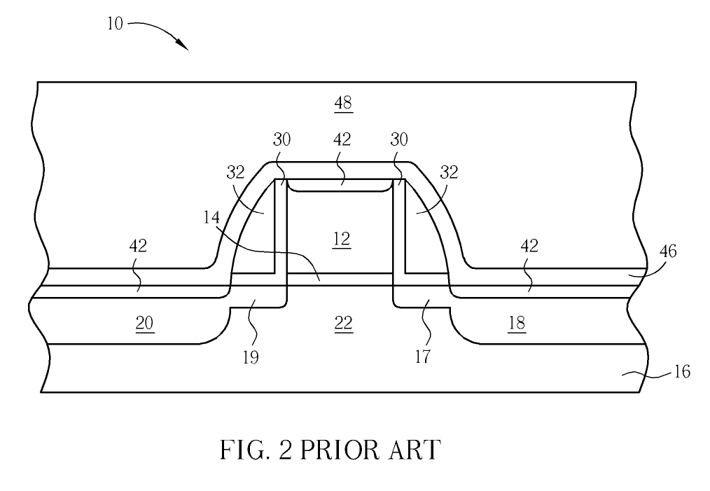

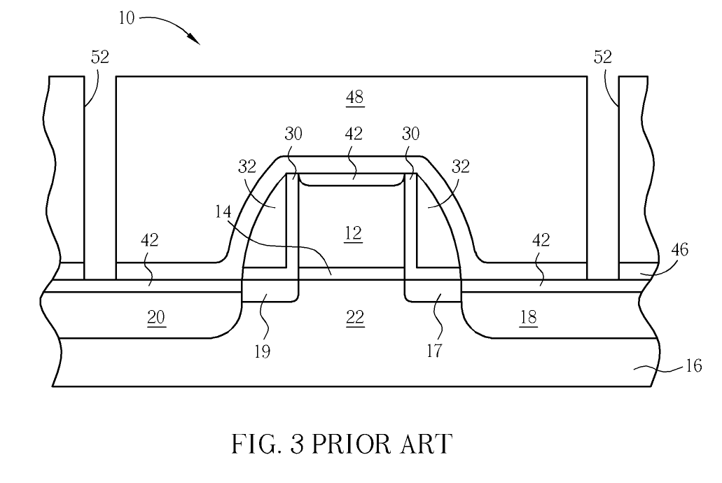

### DETAILED DESCRIPTION

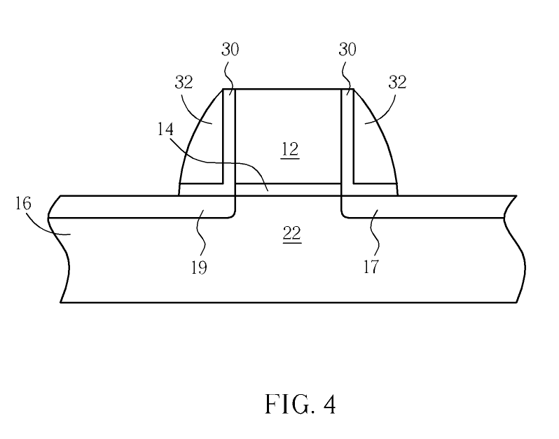

Please refer to FIGS. 4-8. FIGS. 4-8 are schematic cross-sectional diagrams illustrating a method of fabricating semiconductor MOS transistor device 10 in accordance with one preferred embodiment of the present invention, wherein like number numerals designate similar or the same parts, regions or elements. It is to be understood that the drawings are not drawn to scale and are served only for illustration purposes. It is to be understood that some lithographic and etching processes relating to the present invention method are known in the art and thus not explicitly shown in the drawings.

The present invention pertains to a method of fabricating MOS transistor devices, such as NMOS, PMOS, and CMOS devices of integrated circuits. As shown in FIG. 4, a semiconductor substrate generally comprising a silicon layer 16 is prepared. According to this invention, the semiconductor substrate may be a silicon substrate or a silicon-on-insulator (SOI) substrate, but not limited thereto. A shallow-junction source extension 17 and a shallow-junction drain extension 19 are formed in the silicon layer 16. The source extension 17 and drain extension 19 are separated by a channel 22.

A thin oxide layer 14 separates a gate 12 from the channel 22. The gate 12 generally comprises polysilicon. The oxide layer 14 may be made of silicon dioxide. However, in another case, the oxide layer 14 may be made of high-k materials known in the art. Silicon nitride spacer 32 is formed on sidewalls of the gates 12. Liner 30, such as silicon dioxide, is interposed between the silicon nitride spacer and the gate. The liners 30 are typically L shaped and have a thickness of about 30-120 angstroms. the liner 30 may further comprise an offset spacer that is known in the art and is thus omitted in the figures.

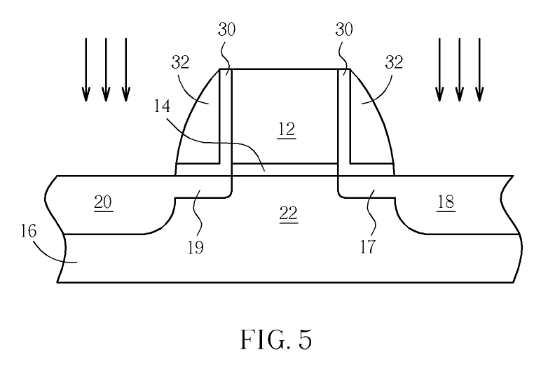

As shown in FIG. 5, after forming the silicon nitride spacer 32, an ion implantation process is carried out to dope dopant species, such as N type dopant species (such as arsenic, antimony or phosphorous) for making an NMOS or P type dopant species (such as boron) for making a PMOS, into the silicon layer 16, thereby forming a source region 18 and a drain region 20. After the source/drain doping, the substrate may be subjected to an annealing and/or activation thermal process that is known in the art.

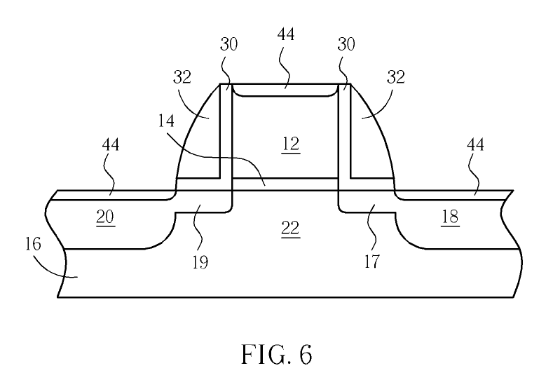

As shown in FIG. 6, a salicide layer 44 is formed on the gate 12, on the exposed source region 18 and on the exposed drain region 20. In order to avoid damage during the subsequent spacer removal, the salicide layer 44 is featured to comprise Si, Ni, and at least one metal selected from a group consisting of Ir, Fe, Co, Pt, Pd, Mo, and Ta.

The salicide layer may be formed by forming a nickel layer and a layer of metal selected from Ir, Fe, Co, Pt, Pd, Mo, and Ta, the layers not being limited to a specific order, or an alloy thereof on the source/drain region and the gate electrode. Then the substrate is subjected to a thermal process, such as annealing or a rapid thermal process to allow the nickel and the metal to react with silicon of the source/drain region and the gate electrode to form the metal silicide layer.

The nickel layer, the layer of metal, or the alloy layer may be formed by a sputtering process, a physical vapor deposition (PVD), or other conventional deposition method, using typical process conditions in the art.

Nickel and the metal are presented in the metal silicide layer in amounts to have an atomic ratio in a range of from 99.5:0.5 to 90:10, and preferably, from 99:1 to 93:7.

In case that a metal silicide layer has been already formed on the source/drain region and the gate electrode as a salicide layer containing only silicon and nickel as in the prior art, a layer of the metal selected from Ir, Fe, Co, Pt, Pd, Mo, and Ta can be formed thereon by a sputtering process, a PVD method, or another conventional deposition method, then subjected to an annealing, such as a rapid thermal process, also resulting in a silicide layer having the aforementioned composition. Thus, the metal silicide layer can avoid damage during the subsequent spacer removal.

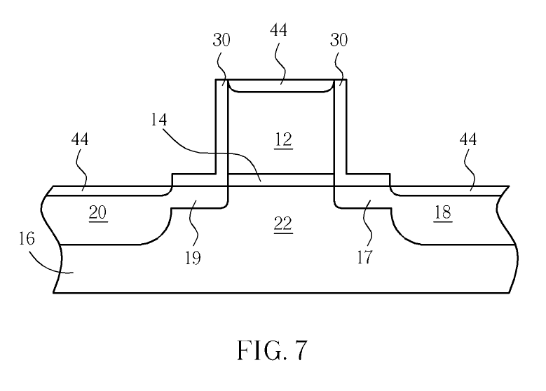

Subsequently, as shown in FIG. 7, the silicon nitride spacer 32 is stripped away, leaving the liner 30 on the sidewalls intact. The silicon nitride spacer 32 may be removed by a dry or wet etching process, while the salicide layer 44 is not damaged by the etching. According to one preferred embodiment, a phosphoric acid solution, especially a hot one at 160° C., may be preferably employed as an etchant to remove the silicon nitride spacer 32. The etchant has an excellent etching selectivity of SiN spacer over the salicide layer having the composition as aforementioned. Accordingly, the SiN spacer is easily etched away and the salicide layer is not damaged.

Please refer to table 1 showing data from the result of etching experiments according to the present invention. In hot phosphoric acid solutions respectively at 150° C. and 160° C., the SiN layer has a blanket etching rate of 45.2 and 63.3 Å/min, and the NiSi layer, 1.1 and 20.3 Å/min, while the Pt—NiSi (Pt:Ni=5:95 in atomic ratio) layer, i.e. the spacer in the present invention, is almost intact.

TABLE 1

Etching Rate (Å/min)

| H₃PO₄ | NiSi | Pt—NiSi | SiO₂ | SiN |
|---|---|---|---|---|
| 150° C. | 1.1 | 0 | 0.07 | 45.2 |
| 160° C. | 20.3 | 0 | 0.09 | 63.3 |

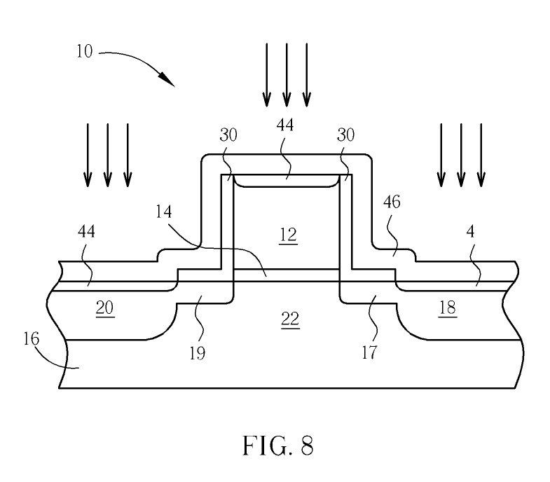

After removing the silicon nitride spacers, approximately L shaped liners are left. However, this invention is not limited to an L shaped liner and the liner may be etched to be thinner or etched away as desired. The resulting substrate may be subsequently processed as desired. As shown in FIG. 8, a conformal silicon nitride cap layer 46 is further deposited on the substrate. Preferably, the silicon nitride cap layer 46 has a thickness of about 30 to 2000 angstroms. The silicon nitride cap layer 46 borders the liner 30 on the sidewalls of the gate 12 of the transistor device 10. The silicon nitride cap layer 46 may be deposited in a compressive-stressed status (for example, −0.1 Gpa to −3 Gpa) for an NMOS or in a tensile-stressed status (for example, 0.1 Gpa to 3 Gpa) for a PMOS to render the channel region 22 a tensile stress or a compressive stress. The alteration of the stress status of the exposed silicon nitride cap layer 46 may be accomplished by using a germanium ion implantation or by using other methods known to those skilled in the art.

Those skilled in the art will readily observe that numerous modifications and alterations of the device and method may be made while retaining the teachings of the invention. Accordingly, the above disclosure should be construed as limited only by the metes and bounds of the appended claims.

1. A method of manufacturing a metal-oxide-semiconductor (MOS) transistor device, comprising:
providing a semiconductor substrate having a main surface;
forming a gate dielectric layer on the main surface;
forming a gate electrode on the gate dielectric layer, wherein the gate electrode has sidewalls and a top surface;
forming a liner on the sidewalls of the gate electrode;
forming a silicon nitride spacer on the liner;
ion implanting the main surface using the gate electrode and the silicon nitride spacer as an implantation mask, thereby forming a source/drain region of the MOS transistor device in the main surface;
forming an alloy layer consisting of nickel (Ni) and at least one metal selected from a group consisting of iridium (Ir), iron (Fe), cobalt (Co), platinum (Pt), palladium (Pd), molybdenum (Mo), and tantalum (Ta) on the source/drain region and the gate electrode and performing a rapid thermal process, thereby the alloy layer reacting with silicon of the source/drain region and the gate electrode to form a salicide layer consisting of silicon (Si), nickel (Ni), and at least one metal selected from a group consisting of iridium (Ir), iron (Fe), cobalt (Co), platinum (Pt), palladium (Pd), molybdenum (Mo), and tantalum (Ta) on the surface of the source/drain region and the gate electrode;
removing the silicon nitride spacer; and
forming a cap layer on the semiconductor substrate, wherein the cap layer borders the liner on the sidewalls of the gate electrode and the salicide layer on the surface of the source/drain region and the gate electrode, and the cap layer has a specific stress status.

2-4. (canceled)

5. The method of claim 1, wherein the salicide layer is formed to comprise nickel and the metal in an atomic ratio of 99.5:0.5 to 90:10.

6. The method of claim 1, wherein the step of removing the silicon nitride spacer is performed by a wet etching process with an etchant containing phosphoric acid.

7. (canceled)

8. The method of claim 1, wherein the cap layer comprises silicon nitride.

9. The method of claim 1, further comprising a step of forming a source/drain extension under the liner.

10-19. (canceled)

20. A method of manufacturing a metal-oxide-semiconductor (MOS) transistor device, comprising:
providing a semiconductor substrate having a main surface;
forming a gate dielectric layer on the main surface;
forming a gate electrode on the gate dielectric layer, wherein the gate electrode has sidewalls and a top surface;
forming a liner on the sidewalls of the gate electrode;
forming a silicon nitride spacer on the liner;
ion implanting the main surface using the gate electrode and the silicon nitride spacer as an implantation mask, thereby forming a source/drain region of the MOS transistor device in the main surface;
forming a nickel salicide layer having an etch damage-free surface on the surface of the source/drain region and the gate electrode, the etch damage-free surface consisting of silicon (Si), nickel (Ni), and at least one metal selected from a group consisting of iridium (Ir), iron (Fe), cobalt (Co), platinum (Pt), palladium (Pd), molybdenum (Mo), and tantalum (Ta);
removing the silicon nitride spacer; and
forming a stressed silicon nitride film on the semiconductor substrate.

21-26. (canceled)

27. The method of claim 20, wherein the salicide layer comprising Si, Ni and at least one metal selected from a group consisting of Ir, Fe, Co, Pt, Pd, Mo, and Ta is formed to comprise nickel and the metal in an atomic ratio of 99.5:0.5 to 90:10.

28. The method of claim 20, wherein the step of removing the silicon nitride spacer is performed by a wet etching process with an etchant containing phosphoric acid.

29-30. (canceled)

31. The method of claim 20, further comprising a step of forming a source/drain extension under the liner.

32. The method of claim 20, wherein forming a nickel salicide layer is performed by forming an alloy layer consisting of nickel (Ni) and at least one metal selected from a group consisting of iridium (Ir), iron (Fe), cobalt (Co), platinum (Pt), palladium (Pd), molybdenum (Mo), and tantalum (Ta) on the surface of the source/drain region and the gate electrode and performing a rapid thermal process on the alloy layer.

33. The method of claim 1, wherein the top surface of the salicide layer comprises metal atoms selected from the group consisting of Ir, Fe, Co, Pt, Pd, Mo, and Ta.
